(19) United States
(12) Patent Application Publication
(10) Pub. No.: US 2026/0047161 A1
(43) Pub. Date: Feb. 12, 2026

(54) A SEMICONDUCTOR STRUCTURE

(71) Applicant: IQE plc, St. Mellons, Cardiff (GB)

(72) Inventors: Andrew CLARK, St. Mellons, Cardiff (GB); Rytis DARGIS, St. Mellons, Cardiff (GB)

(21) Appl. No.: 19/108,502

(22) PCT Filed: Sep. 4, 2023
(86) PCT No.: PCT/EP2023/074147

§ 371 Date: Mar. 4, 2025

(30) Foreign Application Priority Data
Sep. 12, 2022 (GB) 2213277.3

(51) Int. Cl. H10D 62/40; H10D 62/82; H10D 64/68

(52) U.S. Cl. CPC H10D 62/405; H10D 62/82; H10D 64/691; H10D 64/693

(57) ABSTRACT

The present invention provides a semiconductor structure comprising: a silicon substrate in [100] orientation; a scandium oxide layer over the substrate, in [111] orientation; and a scandium-rare earth-oxide layer over the scandium oxide layer. The scandium-rare earth-oxide layer can have a graded composition to transition lattice constant to match to a subsequent layer, such as an indium nitride layer having very high electron drift velocity. InN over Si (100) offers transistors, photonics and passive electronics that operate in the terahertz frequency range.

A semiconductor structure, particularly but not exclusively to provide a template for high frequency electronics.

Many applications require a good quality III-N layer on which to grow or place one or more device layers. For example, a high frequency switch, e.g. metal-oxide semiconductor field effect transistor (MOSFET) or high electron mobility transistor (HEMT), may be grown epitaxially on a III-N layer in order to obtain suitable properties. Typically there are multiple layers on a substrate below the III-N layer.

For epitaxial growth the crystal structure of a layer must match or be compatible with the layer below it. Each layer's crystal alignment is dictated by the lowest energy state of the material and the crystal orientation of the layer below it. Thus for homoepitaxy (growth of the same material as the preceding layer) the crystal orientation will be identical and for most heteroepitaxy (growth of a different material to the preceding layer) the crystal orientation will also be the same. Where the crystal structure of the subsequent layer is different, for example InN in hexagonal form grown on silicon which is cubic, the subsequent layer grows in a compatible crystal orientation. Thus InN grows in the polar [0001] orientation on Si (111) but grows in the semi-polar [11-20] orientation on a (110) rare earth oxide previous layer.

It has previously been determined that crystalline rare earth oxides epitaxially grow with a different crystal orientation to the layer below them. This is called “epi Twist™” by the applicant. This can be used to grow a subsequent layer with a different crystal orientation to the substrate or a previous layer, provided that the lattice constants are approximately matched or that the upper layer has a lattice constant which is an integer multiple of the lattice constant of the lower layer.

Wurtzitic (c-direction) III-N materials such as InN [0001] are preferable in the industry for electronic and photonic devices. For electronic devices, the polar nature of this form of InN is required for a high electron mobility transistor (HEMT) to be fabricated. It is also preferable to use Si (100) substrates because they are widely available, and therefore cheap. They are also commercially available in larger diameters, up to 300 mm, than other orientations of silicon such as Si (111). Furthermore Si (100) offers integration opportunities for photonic devices with electronic devices which are commonly produced on Si (100).

One problem with current InN chips is that to integrate them in a module with the driving electronics it is necessary to bond the GaN chip to a module on Si (100) and then connect them with wires. This introduces an additional failure mode and losses. It may also limit the speed of the device to the current capacity of the wire.

Typically indium nitride (InN) is grown on gallium nitride (GaN). However, there is a relatively high lattice mismatch between InN and GaN which results in a high density of crystallographic defects. Consequently electron mobility is lowered from the theoretical value for InN. InN can also be grown on indium aluminium nitride (InAlN) which is better lattice matched. However, this is complicated because InN and InAlN have very different surface atom mobility and thus different growth temperatures.

The present invention seeks to provide a layer structure that prevents or overcomes the above-mentioned problems.

The present invention provides a semiconductor structure comprising: a silicon substrate in [100] orientation; a scandium oxide layer over the substrate, in [111] orientation; and a scandium-rare earth-oxide layer over the scandium oxide layer.

The semiconductor structure advantageously includes scandium oxide layer which grows in [111] orientation over Si (100) and is crystallographically detached therefrom, and scandium-rare earth-oxide layer which can transition from lattice matched to the scandium oxide layer to lattice matched to a subsequent layer. Advantageously scandium oxide grows in [111] orientation on Si (100), under suitable growth conditions, and therefore does not need to be lattice matched or lattice coincident with the Si (100). Thus the semiconductor structure forms a template for polar III-N layers which are suitable for very high speed electronic and photonic applications on Si (100) substrates which are widely used for electronic devices and are available in large diameters.

The semiconductor structure may further comprise an indium nitride layer over the scandium-rare earth-oxide layer. The indium nitride layer may be polar. Advantageously InN grows in [0001] (polar) orientation on Sc-RE-O (111) because that is its lowest energy state. Advantageously InN (0001) has very high electron mobility and so is suitable for high speed, THz frequency, electronic or photonic applications.

The scandium-rare earth-oxide has composition ScₓRE₁₋ₓO and x may decrease from 1 adjacent to the scandium oxide layer, and where RE is the rare earth element. Advantageously, at x=1 the scandium-rare earth-oxide is ScO and is therefore perfectly lattice matched to the scandium oxide layer. Advantageously decreasing x decreases the proportion of Sc and increases the rare earth (RE) element to adjust (increase) the lattice constant in order to lattice match to a subsequent layer.

x may decrease linearly, stepwise, non-linearly, exponentially, polynomially, or in another grading pattern. Where the change is stepwise the steps may be equal or unequal. For example the thickness grown before x is stepped may be variable and/or the amount by which x decreases may be different between steps. Advantageously the value of x can be decreased in a gradual way so that the lattice constant does not change (increase) too abruptly which would introduce excess strain resulting in defects such as dislocations.

The scandium-rare earth-oxide layer may comprise scandium erbium oxide with composition ScₓEr₁₋ₓO. The value of x may be equal to 0.767 at the layer surface distal to the scandium oxide layer. Advantageously at x=0.767 ScErO is lattice matched to InN.

The scandium-rare earth-oxide layer may comprise scandium yttrium oxide, scandium ytterbium oxide or scandium lutetium oxide. Advantageously each of these compounds can be lattice matched to InN.

The scandium oxide layer may be less than or equal to 20 nm thick. Advantageously a thin layer of scandium oxide is all that is required to stabilise the [111] orientation when grown on Si (100).

The scandium-rare earth-oxide layer may be greater than or equal to 10 nm thick. The scandium-rare earth-oxide layer may be less than or equal to 100 nm thick. The scandium-rare earth-oxide layer may be between 10 nm and 50 nm thick. The lattice constant transition, decrease in the value of x, may be achieved in a layer of 10 nm to 50 nm without introducing strain and/or defects such as dislocations. A thicker layer, up to 100 nm thick in the growth direction, can also function as an insulation buffer between the substrate and a layer or layers grown, deposited or bonded to the scandium-rare earth-oxide layer.

The scandium-rare earth-oxide layer may be lattice matched to the scandium oxide layer. For example, there may be a small or negligible amount of rare earth element immediately adjacent to the scandium oxide layer in order to lattice match.

The indium nitride layer may be lattice matched to the scandium-rare earth-oxide layer. The value of x in the scandium-rare earth-oxide layer may be decreased to a value which lattice matches indium nitride at its upper surface. For example, when the rare earth is erbium, x=0.767 to lattice match. When it is yttria (Y), the value of x to lattice match to InN is 0.786. When it is ytterbium (Yb), the value of x is 0.729 to lattice match to InN. When the rare earth is lutetium (Lu), x=0.68 lattice matches to InN.

The semiconductor structure may further comprise a dielectric layer on the indium nitride layer. The dielectric layer may comprise a crystalline bixbyite oxide. The crystalline bixbyite oxide may be a crystalline rare earth oxide. The crystalline rare earth oxide may be scandium erbium oxide. The dielectric layer may have the same composition as the scandium-rare earth-oxide. For example, the dielectric layer may comprise (Sc_{0.767}Er_{0.233})₂O₃. Advantageously crystalline rare earth oxides are good electric insulators and therefore make good dielectrics. Advantageously using the same material for the dielectric layer as the scandium-rare earth-oxide layer makes it easy to grow in the same epitaxial reactor as no additional elemental sources or precursors are required.

Alternatively the dielectric layer may comprise silicon nitride or a silicon oxide, such as silicon dioxide. Advantageously both these materials are commonly used dielectric materials which can be easily deposited, grown, bonded or sputtered onto the indium nitride layer. Alternatively the dielectric layer may comprise indium oxide, In₂O₃ which has the same crystal structure as the scandium-rare earth-oxide.

The present invention also provides a transistor comprising the semiconductor structure according to any of the preceding paragraphs. Advantageously an InN transistor has very high electron mobility. The transistor may comprise a source, a gate and a drain. Applying a current to the gate results in a very high electron drift through the indium nitride layer between the source and the drain. The transistor may be configured to operate at 1 terahertz (THz) or faster. For example, it may operate at between 1 THz and 4 THz.

The present invention also provides a layered structure comprising: a silicon substrate in [100] orientation, the substrate having a first portion and a second portion; a semiconductor structure as described in any one or more of the paragraphs above, wherein the semiconductor structure is formed on the first portion of the substrate; and a photonics structure formed on the second portion of the substrate. Advantageously the layered structure enables integration of very high speed, ≥1 THz, photonics and electronic components, particularly driving electronics, on a single Si (100) chip. Advantageously it is no longer necessary to pick and place such components and to connect them with wires. Thus the device speed instead of the wires becomes the limiting factor for speed and a failure mode, the wires and connection points, is eliminated.

The present invention also provides a layered structure comprising: a silicon substrate in [100] orientation, the substrate having a first portion and a second portion; a semiconductor structure as described in any one or more of the paragraphs above, wherein the semiconductor structure is formed on the first portion of the substrate; and a passive electronics structure formed on the second portion of the substrate. Advantageously the layered structure enables integration of very high speed, ≥1 THz, passive electronic structures and electronic components, particularly driving electronics, on a single Si (100) chip. Advantageously it is no longer necessary to pick and place such components and to connect them with wires. Thus the device speed instead of the wires becomes the limiting factor for speed and a failure mode, the wires and connection points, is eliminated.

The present invention will be more fully described by way of example with reference to the accompanying drawings, in which:

FIG. 1 is a schematic semiconductor structure according to the present disclosure;

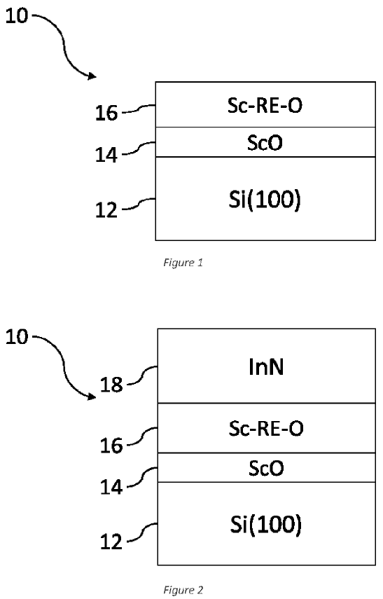

FIG. 2 is a schematic semiconductor structure according to the present disclosure;

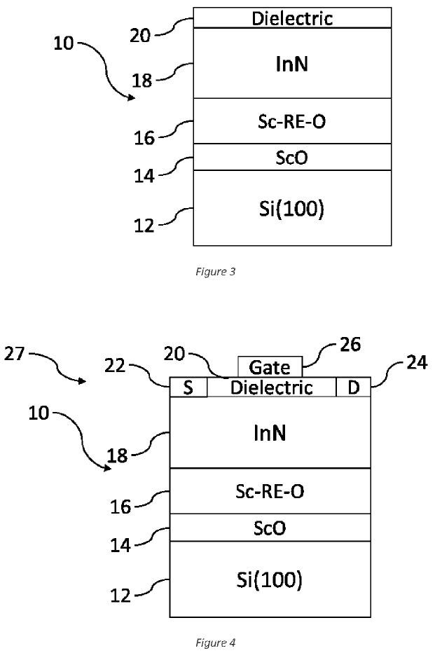

FIG. 3 is a schematic semiconductor structure according to the present disclosure;

FIG. 4 is a schematic semiconductor structure according to the present disclosure;

FIG. 5 is a graph of lattice constant for various III-V compounds;

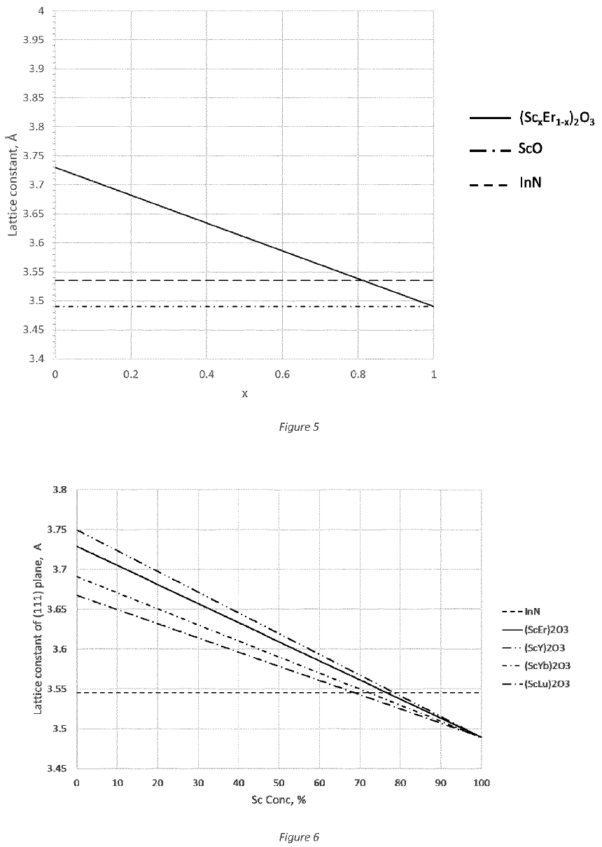

FIG. 6 is a graph of lattice constant for various III-V compounds;

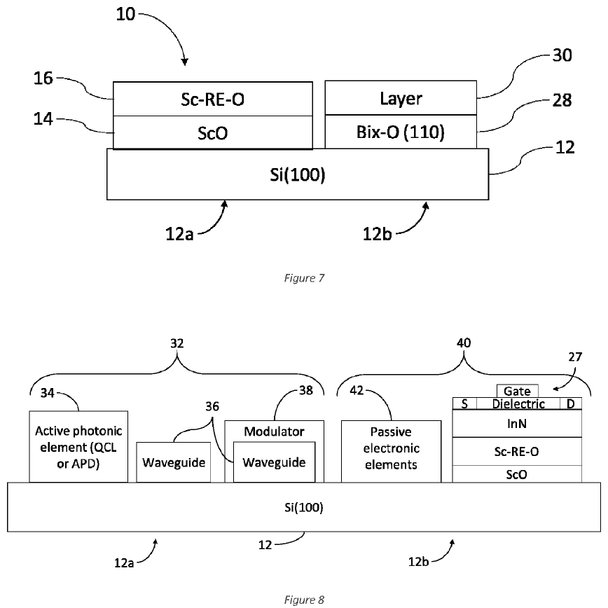

FIG. 7 is a schematic semiconductor structure according to the present disclosure;

FIG. 8 is a schematic semiconductor structure according to the present disclosure.

Epitaxy or epitaxial means crystalline growth of material, usually via high temperature deposition. Epitaxy can be effected in a molecular beam epitaxy (MBE) tool in which layers are grown on a heated substrate in an ultra-high vacuum environment. Elemental sources are heated in a furnace and directed towards the substrate without carrier gases. The elemental constituents react at the substrate surface to create a deposited layer. Each layer is allowed to reach its lowest energy state before the next layer is grown so that bonds are formed between the layers. Epitaxy can also be performed in a metal-organic vapour phase epitaxy (MOVPE) tool, also known as a metal-organic chemical vapour deposition (MOCVD) tool. Compound metal-organic and hydride sources are flowed over a heated surface using a carrier gas, typically hydrogen. Epitaxial deposition occurs at much higher pressure than in an MBE tool. The compound constituents are cracked in the gas phase an then reacted at the surface to grow layers of desired composition.

Deposition means the depositing of a layer on another layer or substrate. It encompasses epitaxy, chemical vapour deposition (CVD), powder bed deposition and other known techniques to deposit material in a layer.

A compound material comprising one or more materials from group III of the periodic table with one or more materials from group V is known as a III-V material. The compounds have a 1:1 combination of group III and group V regardless of the number of elements from each group. Subscripts in chemical symbols of compounds refer to the proportion of that element within that group. Thus Al_{0.25}GaAs means the group III part comprises 25% Al, and thus 75% Ga, whilst the group V part comprises 100% As.

Crystalline means a material or layer with a single crystal orientation. In epitaxial growth or deposition subsequent layers with the same or similar lattice constant follow the registry of the previous crystalline layer and therefore grow with the same crystal orientation. In-plane is used herein to mean parallel to the surface of the substrate; out-of-plane is used to mean perpendicular to the surface of the substrate.

Throughout this disclosure, as will be understood by the skilled reader, crystal orientation <100> means the face of a cubic crystal structure and encompasses [100], [010] and [001] orientations using the Miller indices. Similarly <0001> encompasses [0001] and [000-1] except if the material polarity is critical. Integer multiples of any one or more of the indices are equivalent to the unitary version of the index. For example, (222) is equivalent to, the same as, (111).

Substrate means a planar wafer on which subsequent layers may be deposited or grown. A substrate may be formed of a single element or a compound material, and may be doped or undoped. For example, common substrates include silicon (Si), gallium arsenide (GaAs), silicon germanium (SiGe), silicon germanium tin (SiGeSn), indium phosphide (InP), and gallium antimonide (GaSb).

A substrate may be on-axis, that is where the growth surface aligns with a crystal plane. For example it has <100> crystal orientation. References herein to a substrate in a given orientation also encompass a substrate which is miscut by up to 20° towards another crystallographic direction, for example a (100) substrate miscut towards the (111) plane.

Vertical or out of plane means in the growth direction; lateral or in-plane means parallel to the substrate surface and perpendicular to the growth direction.

Doping means that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type whilst a doped material with extra holes (fewer electrons) is called p-type.

Lattice matched means that two crystalline layers have the same, or similar, lattice spacing and so the second layer will tend to grow isomorphically on the first layer. Lattice constant is the unstrained lattice spacing of the crystalline unit cell. Lattice coincident means that a crystalline layer has a lattice constant which is, or is close to, an integer multiple of the previous layer so that the atoms can be in registry with the previous layer. Lattice mismatch is where the lattice constants of two adjacent layers are neither lattice matched nor lattice coincident. Such mismatch introduces elastic strain into the structure, particularly the second layer, as the second layer adopts the in-plane lattice spacing of the first layer. The strain is compressive where the second layer has a larger lattice constant and tensile where the second layer has a smaller lattice constant.

Where the strain is too great the structure relaxes to minimise energy through defect generation, typically dislocations, known as slip, or additional interstitial bonds, each of which allows the layer to revert towards its lattice constant. The strain may be too great due to a large lattice mismatch or due to an accumulation of small mismatches over many layers. A relaxed layer is known as metamorphic, incoherent, incommensurate or relaxed, which terms are also commonly interchangeable.

A pseudomorphic system is one in which a single-crystal thin layer overlies a single-crystal substrate and where the layer and substrate have similar crystal structures and nearly identical lattice constants. In a pseudomorphic structure the in-plane lattice spacing of the thin layer adopts the in-plane lattice constant of the substrate and is therefore elastically strained, either compressively where the layer has a larger lattice spacing than the substrate or tensilely where the layer has a smaller lattice spacing than the substrate. A pseudomorphic structure is not constrained in the out-of-plane direction and so the lattice spacing of the thin layer in this direction may change to accommodate the strain generated by the mismatch between lattice spacing. The thin layer may alternatively be described as “coherent”, “commensurate”, “strained” or “unrelaxed”, which terms are often used interchangeably. In a pseudomorphic structure all the layers adopt the lattice spacing of the substrate in their respective in-plane lattice spacing.

A layer may be monolithic, that is comprising bulk material throughout. Alternatively it may be porous for some or all of its thickness. A porous layer includes air or vacuum pores, with the porosity defined as the proportion of the area which is occupied by the pores rather than the bulk material. The porosity can vary through the thickness of the layer. For example, the layer may be porous in one or more sublayer. The layer may include an upper portion which is porous with a lower portion that is non-porous. Alternatively the layer may include one or more discrete, non-continuous portions (domains) that are porous with the remainder being non-porous (with bulk material properties). The portions may be non-continuous within the plane of a sublayer and/or through the thickness of the layer (horizontally and/or vertically in the sense of the growth direction). The portions may be distributed in a regular array or irregular pattern across the layer, and/or through it. The porosity may be constant or variable within the porous regions. Where the porosity is variable it may be linearly varied through the thickness, or may be varied according to a different function such as quadratic, logarithmic or a step function.

A porous layer means that pores have been formed through bulk material so that voids are intentionally introduced. Porosity is expressed in percentages which refers to the volume of bulk material which has been removed so 25% porosity means that the 25% of the equivalent volume of bulk material is voided.

A fully depleted porous layer means a layer in which there are no charge carriers.

A crystalline bixbyite oxide layer may be a rare earth oxide layer. The rare earth elements are scandium (Sc), yttrium (Y) and all of the lanthanoid series which is lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu). The bixbyite oxides are bixbyite in crystal structure. Other bixbyite oxides include indium oxide (In₂O₃), vanadium oxide (V₂O₅), iron oxide (Fe₂O₃), manganese oxide (Mn₂O₃) and ternary compounds of a rare earth, a metal and oxygen (RE-M-O).

Where a device is described it should be understood that it will typically be formed on a circular substrate wafer of 4″ (100 mm), 6″ (150 mm), 8″ (200 mm), 12″ (300 mm) or greater diameter. After growth, deposition, bonding and other fabrication steps the devices are separated by dicing the wafer and layers into devices (chips) of appropriate dimensions. Typically tens, hundreds or thousands of devices are cut from a single wafer.

FIG. 1 illustrates an exemplary semiconductor structure 10 according to the present disclosure. The semiconductor structure 10 is comprised of a number of layers. First there is a substrate 12 which is in [100] crystal orientation. The substrate 12 is on-axis silicon (Si), thus it has <100> crystal orientation. As will be understood by the skilled reader, crystal orientation <100> means the face of a cubic crystal structure and encompasses [100], [010] and [001] orientations using the Miller indices. References herein to Si (100) also encompass a silicon substrate 12 which is miscut by up to 20° towards another crystallographic direction, for example towards the (111) plane. Si <100> is readily available in large volumes at relatively low cost because it is used for consumer electronics such as computer chips for processing, memory, or graphics. Si <100> is also widely used for the electronic circuits which drive photonic devices, such as complementary metal-oxide semiconductors (CMOS), because of its high charge carrier mobility (higher than in other orientations of Si). There is therefore an integration benefit to be gained by growing the photonic device on Si <100>, with suitable layers in between, if sufficient crystal quality can be obtained. Where a device grown on Si (100) is the driving power electronic device for that grown on the layered structure described herein this may obviate the need for wiring to connect the devices. Advantageously the device performance becomes the speed-limiting factor and not the wiring. Advantageously a potential failure mode is removed by omitting the wiring.

The silicon substrate 12 may be monolithic; that is comprising bulk single crystal silicon throughout. Alternatively the silicon substrate 12 may also comprise porous silicon for some or all of its thickness, for example it may form a sublayer. The substrate 12 may include an upper portion which is porous with a lower portion that is non-porous. Alternatively the substrate 12 may include one or more discrete, non-continuous portions that are porous with the remainder being non-porous (with bulk silicon properties). The portions may be non-continuous within the plane of a sublayer and/or through the thickness of the layer (horizontally and/or vertically in the sense of the growth direction). The portions may be distributed in a regular array or irregular pattern across the substrate 12, and/or through it. The porosity may be constant or variable within the porous regions. Where the porosity is variable it may be linearly varied through the thickness, or may be varied according to a different function such as quadratic, logarithmic or a step function.

Alternatively the substrate may comprise silicon-germanium (SiGe), for example Si_{0.8}Ge_{0.2}, or silicon on insulator (SOI).

On or over the substrate 12 is a scandium oxide layer 14. The scandium oxide layer 14 may be positioned on, grown on or over, or deposited on the substrate 12. Preferably the scandium oxide layer 14 is epitaxially grown (deposited) on the substrate 12 to form a layer adjacent thereto. It is easier to obtain high quality, good crystallinity by epitaxial deposition or growth.

When a crystalline bixbyite oxide, such as scandium oxide or another rare earth oxide, is deposited on a substrate 12, or another layer, at sufficient surface temperature, low enough oxygen concentration and slow enough growth rate it does not match the crystal orientation of the previous layer, depending on the orientation of the substrate 12 or previous layer. Instead it grows in a different orientation, a process called “epi Twist™” by the inventors. When growing most crystalline bixbyite oxides on Si (100) the crystalline bixbyite oxide layer grows in [110] orientation which has lower surface energy than [100] orientation.

Scandium oxide, which is a rare earth oxide but not in the lanthanoid series of elements, surprisingly behaves differently to other crystalline bixbyite oxides, particularly rare earth oxides, in that its lowest energy orientation is [111] and so it grows in this orientation on Si (100). The preferred crystal orientation of a material is dependent on its surface energy and the lattice mismatch to the layer below. The arrangement of the atoms within the crystal is also a factor since this affects the spacing between atoms on different surfaces, and whether a surface has only oxygen atoms, only metal atoms or a combination of both. Sc is a smaller atom than the other rare earth elements and the lattice spacing of Sc₂O₃ is smaller than for other crystalline bixbyite oxides. Therefore Sc₂O₃ (111) exhibits a greater lattice mismatch to Si (100): around −9%. For this reason the surface energy becomes the dominant factor to define crystal orientation whereas in crystalline bixbyite oxides which are better lattice matched to Si (100), for example up to ±2%, the lattice match is the dominant factor even though the surface energy in (110) orientation may be twice that in (111) orientation.

The scandium oxide layer 14 only needs to be thick enough for the [111] orientation to stabilise on the Si(100) substrate 12. For example it may be around 20 nm thick in the growth direction.

Positioned on, grown on or over, or deposited on the scandium oxide layer 14 is a scandium-rare earth-oxide layer 16. The scandium-rare earth-oxide layer 16 grows in [111] orientation on the scandium oxide layer 14. The scandium-rare earth-oxide layer 16 may comprise scandium erbium oxide, ScErO. For example, the scandium erbium oxide may have composition ScₓEr₁₋ₓO with x selected to lattice match to an adjacent layer. The scandium erbium oxide layer 16 acts to transition from the lattice constant of scandium oxide, approximately 3.49 Å, to the lattice constant of a subsequent layer.

The composition of the scandium-rare earth-oxide layer 16 may change through the layer. For example, x may decrease from 1 adjacent to the scandium oxide layer 14 to a desired value to lattice match a layer to be grown or deposited thereon. The value of x may decrease linearly from 1 to the lattice match value or may be decreased in another grading pattern, for example stepwise, or non-linearly such as exponentially, parabolically or otherwise. By increasing the Er content of the layer, and decreasing the Sc content, the lattice constant is increased as shown in FIG. 5. In FIG. 5 it can be seen that the lattice constant of ScₓEr₁₋ₓO, as indicated by the solid line, decreases linearly from 3.73 Å when x=0 (ErO) to 3.49 Å when x=1 (ScO, shown with the dot-dash line).

Alternatively the scandium-rare earth-oxide layer 16 may comprise a different compound such as scandium yttrium oxide (ScYO), scandium ytterbium oxide (ScYbO) or scandium lutetium oxide (ScLuO). FIG. 6 shows each of these compounds plotted with lattice constant against the percentage of Sc. 0% Sc is the same as x=0 and 100% Sc is the same as x=1 in FIG. 5. Y₂O₃ (dash-dot-dot line) has the largest lattice constant, 3.749 Å, then Er₂O₃ (solid line) at 3.727 Å, Yb₂O₃ (dash-dot line) at 3.691 Å, and finally Lu₂O₃ (long dash-dot line) at 3.666 Å. as with (ScₓEr₁₋ₓ)₂O₃ the value of x may decrease linearly through the scandium-rare earth-oxide layer 16, from x=1 to a desired value to lattice match to a subsequent layer, or may decrease in another grading pattern, such as stepwise, exponentially, parabolically or otherwise.

The semiconductor structure 10 may be grown by molecular beam epitaxy (MBE). Alternatively it may be grown by metal-organic vapour phase epitaxy (MOVPE, also known as metal-organic chemical vapour deposition, MOCVD). Alternatively it may be grown by atomic layer deposition (ALD).

The semiconductor structure 10 may be a template for growth, deposition or bonding of an additional layer or layers, such as device layers. Such a template comprises the substrate 12, scandium oxide layer 14 and scandium-rare earth-oxide layer 16.

In another aspect of the disclosure the semiconductor structure 10 may include one or more additional layers, as shown in FIG. 3. An indium nitride layer 18 is over the scandium-rare earth-oxide layer 16. The indium nitride layer 18 may be positioned on, grown on or over, or deposited on the scandium-rare earth-oxide layer 16. Preferably it is epitaxially grown. The indium nitride layer 18 may be in [0001] crystal orientation, that is polar orientation, due to the way in which it is nucleated. The polarity, N-polar or In-polar, affects the carrier mobility. The [0001] orientation is the lowest energy state for indium nitride grown over scandium-rare earth-oxide (111). Advantageously polar indium nitride (InN) has very high electron drift velocity making it suitable for transistors operating at high frequency, for example at 1 THz or faster. InN has a lattice constant of 3.545 Å, as shown by the dashed line in FIG. 5 and FIG. 6.

The indium nitride layer 18 may be grown by MBE or by MOVPE. Alternatively it may be deposited, for example by sputtering, or bonded to the template.

When InN is under strain due to lattice mismatch the density of crystallographic defects increases which scatters charge carriers (electrons) thereby reducing their drift velocity. Thus it is beneficial to use the scandium-rare earth-oxide layer 16 to transition the lattice constant to match InN. Where the scandium-rare earth-oxide is (ScₓEr₁₋ₓ)₂O₃ it is lattice matched to InN with x=0.767. Thus the value of x can be decreased from 1 to approximately 0.767 through the thickness of the scandium-rare earth-oxide layer 16 in the growth direction. For example, x may be decreased linearly or stepwise, in equal or unequal steps, from x=1 to x=0.767. For (ScₓY₁₋ₓ)₂O₃ the value of x to lattice match to InN is 0.786; for (ScₓYb₁₋ₓ)₂O₃ it is 0.729; and for (ScₓLu₁₋ₓ)₂O₃ it is 0.68. In some circumstances it may be beneficial to set the value of x so that the InN is not quite lattice matched to the scandium-rare earth-oxide layer 16. In this case the compressive or tensile strain which results (less than 1%, for example 0.2% to 0.5%) may enhance material or device properties, such as drift velocity, to a greater extent than when fully lattice matched.

The scandium-rare earth-oxide layer 16 may achieve lattice matching to the next layer, for example the indium nitride layer 18, in 10 to 50 nm thickness. Alternatively it may be thicker, for example up to 100 nm, to additionally act as an insulating buffer for specific devices grown in or over the indium nitride layer 18.

On or over the indium nitride layer 18 may be a dielectric layer 20, as shown in FIG. 3. The dielectric layer 20 may comprise a crystalline rare earth oxide. For example it may comprise scandium-rare earth-oxide of the same composition as the scandium-rare earth-oxide layer 16, such as scandium erbium oxide. Alternatively it may comprise a different rare earth oxide. Alternatively it may comprise a different dielectric, such as silicon nitride (SiNₓ) or silicon dioxide (SiO₂).

The dielectric layer 20 may be fabricated into a device such as a FET, shown in FIG. 4. Thus transistor 27 comprises a source 22 and drain 24 which may be formed by etching away portions of the dielectric so that the indium nitride layer 18 is exposed and depositing the source 22 and drain 24. A gate 26 may be formed over the dielectric layer 20, for example in a central portion, to switch the current flow from source 22 to drain 24 via the indium nitride layer 18 or block flow of electrons. The indium nitride layer 18 has very high electron drift velocity and thus enables switching at terahertz frequencies, for example at greater than or equal to 1 THz up to, for example, 4 THz. Thus the semiconductor structure 10 is suitable for fabrication into a FinFET, MOSFET or other transistor. Advantageously an InN FinFET gives more charge than a Si-based FinFET.

There are many terahertz applications, for example in imaging and spectroscopy where high frequency enables higher resolution. Far-infrared devices, operating at 75-300 μm (1-4 THz), can be used for security, sensing and wireless applications. For example, security screening at airports can make use of THz frequency transistors to detect explosives, concealed weapons and biological agents. In this case the dielectric layer 20 may be a high-K dielectric. Imaging at sub-300 μm wavelengths in medical settings may assist in early diagnosis of diseases such as cancer. Terahertz frequencies are also beneficial in astronomy, for spectroscopy, for transportation, for radar and LiDAR, and for communication.

Currently InN devices such as HEMTs are connected to Si-based CMOS electronics by wire, for example in telecommunication or internet base stations. The wiring presents a potential failure mode. It may also limit the speed of operation. The present invention permits the growth of InN devices over Si (100) substrates which can also host CMOS electronics. Since the CMOS electronics and InN devices are adjacent the wiring is obviated which removes the associated failure modes and means that device performance is governed by the devices themselves and not by the limitations of the connections. Advantageously the ability to grow InN (0001) means that the inherent charge is available, since the GaN is polar, which enables piezoelectric switching without doping. The InN device may be configured to manage power, for example by performing step-down voltage conversion in a microprocessor.

Similarly, for LED or μLED applications an InN-based emitter, or an array of InN-based emitters, can be grown on Si (100) according to the present semiconductor structure 10. Thus the InN layer 18 may be replaced by a compound including InN which forms quantum wells that emit light, for example red light at around 650 nm. The indium nitride layer 18 may comprise sublayers such that the quantum wells are surrounded by cladding layers including some aluminium, AlInN. The value of x to lattice match to AlInN may be different to that required to lattice match to InN. Each emitter corresponds to one pixel of a display. The emitter or emitters can be controlled by electronic control components or devices which are also grown on or mounted on Si (100). Thus the emitters and controls can be collocated, preferably adjacent, so that each pixel in an array can be individually addressed easily and directly. Advantageously the pixels can be lit and switched off quickly and accurately.

For example, the semiconductor structure 10 may be grown on a first part (portion) 12a of a Si (100) substrate 12 with electronic control components grown on a second part (portion) 12b of the Si (100) wafer as shown in FIG. 7. The second part 12b of the wafer (substrate 12) may include a bixbyite oxide layer 28 in [110] orientation. The bixbyite oxide layer 28 may comprise erbium oxide (Er₂O₃) which twists to [110] orientation when grown on Si (100). A layer 30 can then be grown which is compatible with the [110] orientation. For example, the layer 20 may comprise molybdenum (Mo) in [112] orientation.

Alternatively the semiconductor structure 10 may be grown on a first part 12a of a Si (100) substrate 12 with electronic circuits grown directly on another part (second portion 12b) of the Si (100) substrate 12, without an intervening bixbyite oxide layer 28.

Advantageously growth of indium nitride on the semiconductor structure 10 enables integration of THz frequency photonics or passive electronics structures (such as resistors, capacitors, inductors which drive a transistor) with electronic circuits on the same chip without the need for frequency converters. For example, as shown in FIG. 8, Si photonics 32 such as active photonic elements 34 (quantum cascade laser, QCL, or avalanche photodiode, APD, for example), waveguides 36 and modulators 38 can all be grown or fabricated on a first portion 12a of a Si (100) substrate 12 and operate at THz frequencies. Electronics 40 operating in the terahertz frequency range include the semiconductor structure 10 configured as a transistor 27 and passive electronic components 40. Advantageously they can be grown or fabricated on a second portion 12b of the same Si (100) substrate 12. Advantageously no frequency converter is required because the photonic 32 and electronic 40 components all function in the same frequency range. By integrating the photonic and electronic components on the same substrate 12 fabrication is less complex, it requires no interconnects, lift-off or frequency converters, and is therefore cheaper and more reliable.

1. A semiconductor structure comprising:
a silicon substrate in [100] orientation;
a scandium oxide layer over the substrate, in [111] orientation; and
a scandium-rare earth-oxide layer over the scandium oxide layer.

2. The semiconductor structure of claim 1, further comprising an indium nitride layer over the scandium-rare earth-oxide layer.

3. The semiconductor structure of claim 2, wherein the indium nitride layer is polar.

4. The semiconductor structure of claim 1, wherein the scandium-rare earth-oxide layer has composition ScₓRE₁₋ₓO and wherein x decreases from 1 adjacent to the scandium oxide layer, and where RE is a rare earth element.

5. The semiconductor structure of claim 1, wherein the scandium-rare earth-oxide layer comprises scandium erbium oxide having composition ScₓEr₁₋ₓO and wherein x is equal to 0.767 at the layer surface distal to the scandium oxide layer.

6. The semiconductor structure of claim 1, wherein the scandium oxide layer is less than or equal to 20 nm thick.

7. The semiconductor structure of claim 1, wherein the scandium-rare earth-oxide layer is greater than or equal to 10 nm thick and/or is less than or equal to 100 nm thick.

8. The semiconductor structure of claim 1, wherein the scandium-rare earth-oxide layer is between 10 nm and 50 nm thick.

9. The semiconductor structure of claim 1, wherein the scandium-rare earth-oxide layer is lattice matched to the scandium oxide layer.

10. The semiconductor structure of claim 1, wherein the scandium oxide layer is crystallographically detached from the substrate.

11. The semiconductor structure of claim 2, wherein the indium nitride layer is lattice matched to the scandium-rare earth-oxide layer.

12. The semiconductor structure of claim 2, further comprising a dielectric layer on the indium nitride layer.

13. The semiconductor structure of claim 12, wherein the dielectric layer comprises a crystalline bixbyite oxide, a crystalline rare earth oxide, scandium erbium oxide, silicon nitride, silicon oxide, or indium oxide.

14. The semiconductor structure of claim 12, wherein the dielectric layer has the same composition as the scandium-rare earth-oxide layer.

15. A transistor comprising the semiconductor structure of claim 1.

16. The transistor of claim 15, configured to operate at 1 terahertz or faster.

17. A layered structure comprising:
a silicon substrate in [100] orientation, the substrate having a first portion and a second portion;
a semiconductor structure as claimed in claim 1, wherein the semiconductor structure is formed on the first portion of the substrate; and
a photonics structure or passive electronics structure formed on the second portion of the substrate.
